(19) United States
(12) Patent Application Publication
(10) Pub. No.: US 2026/0239571 A1
(43) Pub. Date: Aug. 13, 2026

(54) HEAT SINK WITH CORRUGATED FINS

(71) Applicants: DENSO International America, Inc., Southfield, MI (US); DENSO CORPORATION, kARIYA (JP)

(72) Inventor: Siddharth DASGUPTA, Windsor (CA)

(21) Appl. No.: 19/050,696

(22) Filed: Feb. 11, 2025

(51) Int. Cl. H05K 7/20

(52) U.S. Cl. CPC H05K 7/2039

(57) ABSTRACT

A heat sink includes a base and a plurality of joined fins extending upwardly from the base. Each joined fin includes two individual fins that are joined or formed together to create a single fin. The joined fins are arranged in rows along a longitudinal direction to define channels between the rows. Each joined fin of each row is joined to an adjacent one of the joined fins in the same row such that each row of the joined fins is contiguous to inhibit fluid from flowing from one of the channels to another of the channels. Each of the joined fins has a corrugated outer surface. The corrugated outer surface can be a vertical corrugation, a horizontal corrugation, and can exist in only specific locations of the joined fins.

### TECHNICAL FIELD

The present disclosure relates to pin fins for a heat sink for improving heat transfer efficiency. In embodiments, the present disclosure relates to fins of a heat sink, wherein the fins have a corrugated profile to improve heat transfer efficiency.

### BACKGROUND

The performance, lifespan, and safety of many electrical components are dependent on the temperature at which the electrical components operate and a build-up of heat can negatively affect these elements. The temperature of the electrical component may be affected by heat generated from the electrical component or its surrounding environment. Heat sinks are used to dissipate heat from electrical components or other heat-generating devices and prevent the negative effects from a build-up of heat. Some heat sinks use pin fins that extend outward from a base that is in thermal communication with the electrical component. As fluids (e.g., air, water, or the like) flow along the heat sink through the pin fins, the pin fins transfer the heat from the electrical component to the fluid, cooling the electrical component.

### SUMMARY

According to an embodiment, a heat sink comprises: a base; and a plurality of joined fins extending upwardly from the base, wherein the joined fins are arranged in rows along a longitudinal direction to define channels between the rows, wherein each joined fin of each row is joined to an adjacent one of the joined fins in the same row such that each row of the joined fins is contiguous to inhibit fluid from flowing from one of the channels to another of the channels; wherein each of the joined fins has a corrugated outer surface.

According to an embodiment, a heat sink comprises: a base having an inlet region configured to receive incoming fluid, and an outlet region on an opposite end of the base from the inlet region; and a plurality of fins extending upwardly from the base, each fin having a leading surface facing the inlet region and a trailing surface facing the outlet region; wherein at least one of the leading surfaces or the trailing surfaces are corrugated.

In some embodiments, only the trailing surfaces are corrugated. In some embodiments, both the trailing and the leading surfaces are corrugated. In yet other embodiments, only the leading surfaces are corrugated.

In an embodiment, a heat sink comprises: a base having an inlet region configured to receive incoming fluid, and an outlet region on an opposite end of the base from the inlet region; and a plurality of fins extending upwardly from the base, each fin having a lower region adjacent to the base and an upper region; wherein at least one of the lower region and upper region of each fin has a vertical cross-sectional profile that includes a plurality of vertical corrugations.

In embodiments, only the upper regions are corrugated. In other embodiments, only the lower regions are corrugated. In yet other embodiments, both the upper and lower regions are corrugated.

### BRIEF DESCRIPTION OF THE DRAWINGS

FIG. 1A is a top plan view of a heat sink according to an embodiment.

FIG. 1B is a perspective view of the heat sink of FIG. 1A.

FIG. 2A is a top plan view of a heat sink according to another embodiment.

FIG. 2B is an enlarged view of a region of the heat sink of FIG. 2A showing a fin having a horizontal corrugation.

FIG. 3A is a top plan view of a heat sink according to another embodiment.

FIG. 3B is a perspective view of a region of the heat sink of FIG. 3A showing fins having vertical corrugations.

FIG. 4 is a side cross-sectional view of a region of a heat sink according to another embodiment.

FIG. 5A is a top plan view of a heat sink according to another embodiment.

FIG. 5B is an enlarged view of a region of the heat sink of FIG. 5A showing joined fins with horizontal corrugations.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations. “A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

Inverter cards are electronic components commonly used to convert direct current (DC) to alternating current (AC) in various applications, such as powering AC motors, lighting, and devices from a DC source. These cards are integral to power electronics systems, including renewable energy setups (e.g., solar power systems), electric vehicles, and uninterruptible power supplies (UPS). Inverter cards typically include several heat-generating components, such as power transistors, driver circuits, capacitors, and inductors, as well as integrated circuits (ICs) that perform control, processing, and support functions.

During operation, the power transistors and other components on an inverter card can generate significant heat, necessitating the use of heat sinks to prevent overheating and ensure reliable performance. Heat sinks, typically made from thermally conductive materials such as aluminum or copper, transfer heat away from the components to the surrounding air or fluid (gas or liquid). This transfer occurs through direct contact or via thermally conductive pads or pastes. However, conventional heat sink designs, such as those using pin fins, may struggle to dissipate heat efficiently in high-density or high-performance applications like inverter cards. Limited surface area and suboptimal thermal management can lead to overheating, compromising component performance and lifespan. There is a need for improved heat sink designs that enhance heat dissipation by maximizing surface area and optimizing fluid flow, addressing the thermal challenges posed by modern inverter card designs.

Therefore, according to various embodiments disclosed herein, the present disclosure provides a heat sink featuring fins with corrugated shapes. The corrugated geometry of the fins increases the overall surface area available for heat transfer, enhancing the dissipation of heat from the heat-generating components to the surrounding fluid. By maximizing the contact area between the heat sink and the fluid, the corrugated fins promote more efficient thermal management, even in high-density or high-performance applications such as inverter cards. This improved design reduces the risk of overheating, thereby protecting the components and extending their operational lifespan.

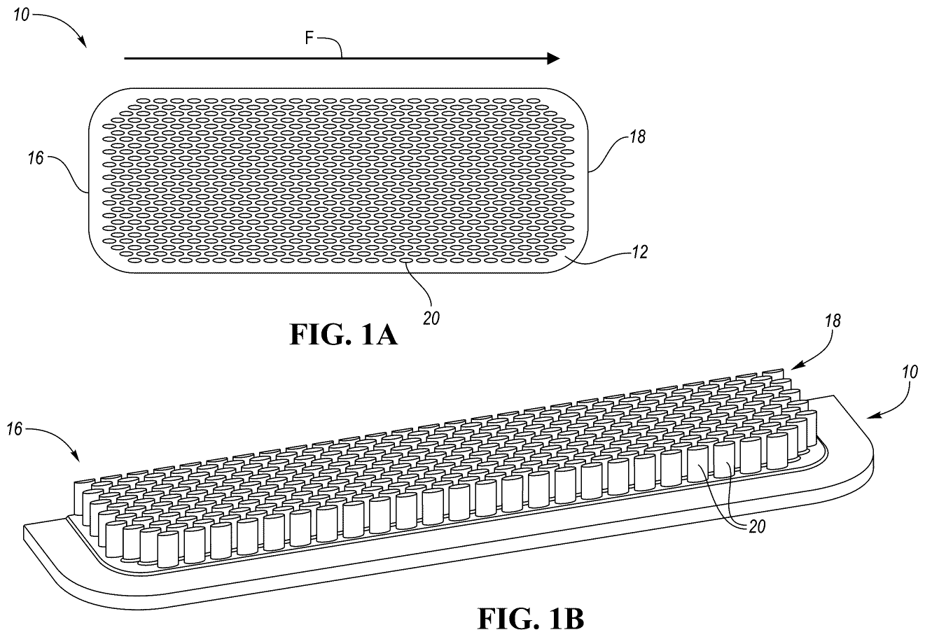

Referring to FIGS. 1A and 1B, a heat sink 10 for dissipating heat from a heat-generating device (e.g., an electrical or computer component, an inverter card, a power card, or the like) is illustrated. The heat sink includes a substrate or base 12 surrounded by an outer plate. The heat sink 10 may be attached to the heat-generating device via the outer plate, a thermal paste, a connecting component between the heat sink 10 and the device, or the like. The heat-generating device may be attached to a bottom side of the heat sink which is not visible from the top view shown in these Figures. The heat sink 10 may also be connected to a housing (e.g., via the outer plate) that encloses the heat sink 10 for containing and exposing the base 12 to a fluid, such as water, air, refrigerant, oil, dielectric fluid, or some other non-conductive thermal transfer fluid, or the like. The fluid is conveyed (by forced or natural convection) through the heat sink 10 from an inlet region 16 (also referred to as a first side) to an outlet region 18 (also referred to as a second side opposite the first side), such that the fluid travels along the fluid flow direction indicated by arrow F. The fluid flow direction is a generally longitudinal direction from the inlet region 16 to the outlet region 18.

The heat sink 10 includes a plurality of fins 20 that extend outwardly from the base 12 and along the base 12 from the first side 16 to the second side 18 in a staggered arrangement. The fins 20 (e.g., pins, pin fins, projections, protrusions, or the like) are configured to increase the surface area of the heat sink for more effective heat transfer. In this embodiment, the fins 20 have an elliptical shape or airfoil shape. As the fluid flows through the heat sink 10 in the general direction of F, the flow separates due to an adverse pressure gradient; the fluid can recirculate in a space between the fins 20 with a fluid velocity opposite to the flow direction. The recirculation and potential velocity stagnation results in a diminished heat transfer efficiency and a greater pressure drop.

The corrugated surface can increase the surface area of the fins, thus resulting in increased heat transfer between the fins and the passing fluid. The amount, nature, and specifics of the corrugation can vary.

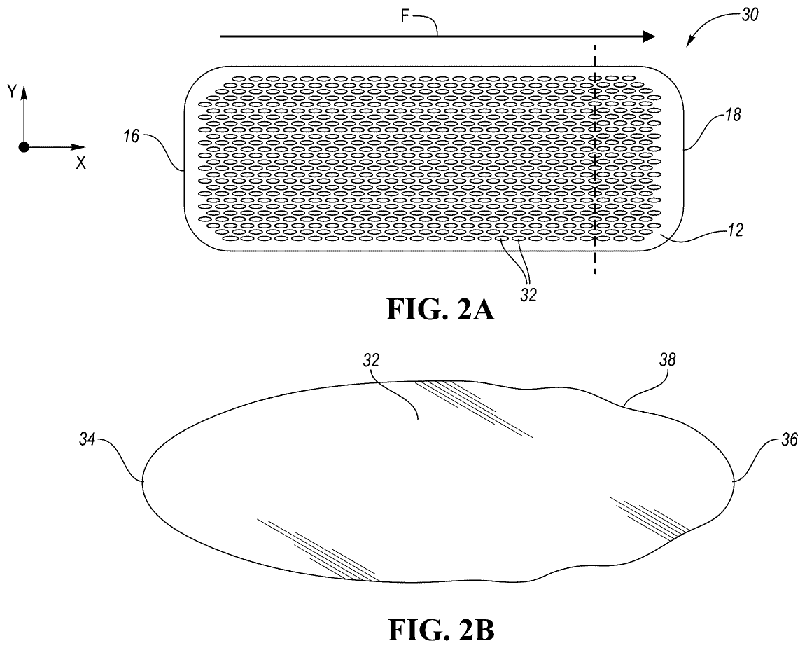

For example, in one embodiment illustrated in FIGS. 2A-2B, the downstream side of at least some of the fins is corrugated. Referring to FIGS. 2A-2B, once again a heat sink 30 is illustrated. It should be understood that the heat sink 30 of this embodiment can incorporate all of the features of the heat sink 10 of FIGS. 1A-1B unless the description and context described herein dictates otherwise. Here, the heat sink 30 includes a plurality of fins 32. Each fin 32 includes a leading surface or leading side 34, and a trailing surface or trailing side 36. The leading side 34 is generally upstream of the trailing side 36 in that the leading side 34 faces the general direction of the inlet region 16, and the trailing side 36 faces the general direction of the outlet region 18.

In this embodiment, and as shown in FIG. 2B, the trailing side 36 of the fins 32 are corrugated, or provided with a corrugated surface 38. The corrugations on the trailing side 36 of the fins 32 can be formed by way of additive manufacturing such as 3D printing, for example, which enables very precise, minute surface feature formation. The corrugations can be or include a series of ridges and grooves that extend about at least a portion of the trailing side 36. Each fin 32 can be provided with several ridges and grooves such that the entire outer surface of each fin is corrugated. These corrugations of FIG. 2B can be referred to as horizontal corrugations in that they are visible with a horizontal cross-section such as the one taken in FIG. 2B. In other words, when viewed from a horizontal cross-section (e.g., FIG. 2B), the fins 32 have a corrugated trailing surface 36 and a smooth leading surface 34; the horizontal corrugations extend (and are visible in) a horizontal plane of the fins. The corrugations can be located along the entire height (e.g., Z-axis) of each fin 32, from their lower ends to their upper ends. Alternatively, in other embodiments, the corrugations can extend only partially in the direction of the height (e.g., Z-axis) of each fin 32.

The corrugations 38 are shown as extending about roughly half of the perimeter of the fin 32. However, in other embodiments, the corrugations are located along more or less of the perimeter. For example, in some embodiments, the corrugations are located along only roughly (25%) of the surface of the fin 32 at the trailing surface 36. In some embodiments, the corrugations are located at or around only the trailing edge or apex of the fin 32.

It should also be noted that the examples shown in the Figures are not limiting on the scope of this disclosure, unless specifically claimed. In other embodiments, the amplitudes (e.g., peak to peak) of the corrugations can vary from what is shown. For example, the amplitudes of the corrugations can vary from fin to fin, or within a single fin. Also, the number of corrugations can vary from fin to fin.

While not shown in these Figures, in other embodiments the corrugations are provided on both the leading side 34 and the trailing side 36 of at least some of the fins 32. In other words, the present disclosure is not limited to having only a trailing side 36 be corrugated; rather, the entire outer surface (leading and trailing) may be corrugated.

Likewise, not all of the fins 32 need to be corrugated. Rather, in embodiments only some of the fins 32 have a corrugated outer surface. For example, in some embodiments, only a select region or regions of the array of fins 32 has corrugations. There can be a region of fins that have no corrugated outer surface, and another region of fins in which all of the fins in that region have a corrugated outer surface. The varying arrangement of corrugated fins can be customized depending on the specific heat transfer qualities of a particular heat sink.

The corrugated surface profile of the fins 32 helps improve heat transfer in multiple ways. For example, consider the Nusselt number (Nu=hL/K), where K is the thermal conductivity of the fluid and where the heat transfer coefficient (h) is inversely proportional to the fin length (L) at constant Nusselt number. This implies that increasing the length of the fin generally reduces the heat transfer efficiency because the longer flow path leads to less boundary layer gradients and lower heat transfer rates. The Nusselt number helps explain how the geometry of the fins influences heat transfer. As the fin length increases, the Nusselt number tends to decrease, leading to a reduced heat transfer coefficient (h). Thus, long, smooth fins are generally less efficient at transferring heat—the flow along the fin surface becomes more stable, forming a thicker boundary layer that impedes heat exchange between the fluid and the fin surface. However, with corrugated fins, the surface is deliberately designed to disrupt the fluid flow, promoting turbulence and enhancing the convective heat transfer. The corrugations cause the flow to detach and reattach along the surface, which reduces the boundary layer thickness and increases the heat transfer coefficient (h). This disruption in the flow dynamics leads to an increase in the Nusselt number, which indicates a more efficient heat transfer process.

Having a corrugated surface on the trailing (rear) surface 36 of the fin, as opposed to the leading surface 34, can be advantageous for several additional reasons. For example, this design can impact flow development. As fluid flows along the surface of the fin, the flow is generally still developing when it first contacts the fin's leading surface 34. Placing the corrugations on the trailing surface 36 allows the flow to develop along the fin's length before encountering the disruption. The flow at the trailing surface 36 can be more established and may already be moving at a higher velocity or with more turbulence, making it better suited to handle the disruptions caused by the corrugations. This allows the fluid to mix more effectively and disrupt the boundary layer at a later stage, improving heat transfer without negatively affecting the initial flow behavior.

Second, corrugations can impact the attachment and reattachment of flow. As fluid flows over the fin 32, it attaches to the fin surface and detaches near the trailing edge. Corrugations on the trailing surface 36 help promote this attachment and reattachment process, which can create additional turbulence and mixing in the fluid. This disruption can be particularly effective on the trailing side 36 because it ensures that the flow's boundary layer is thinned out, enhancing heat transfer as the fluid moves over the fin.

Third, the corrugations can control the thermal boundary layer. The thermal boundary layer is the temperature profile of the layer of fluid in contact with the fin surface. The thermal boundary layer can become quite thick as the fluid moves along the fin 32, reducing heat transfer efficiency. Corrugating the trailing surface 36 can help break up this layer, facilitating more efficient heat transfer by encouraging turbulence and mixing in the fluid. This is particularly beneficial toward the trailing surface 36 where the thermal gradient may already be lower.

And fourth, the corrugations can minimize flow separation. The leading side 34 of the fin is where flow separation can occur, particularly in cases of abrupt changes in surface geometry. Introducing corrugations on the trailing side 36 minimizes the risk of early flow separation, which can create dead zones and reduce heat transfer. The corrugations at the trailing surface 36 enhance flow attachment and reattachment, preventing or reducing separation further downstream. In other embodiments, joining the fins together can also minimize flow separation without requiring corrugations.

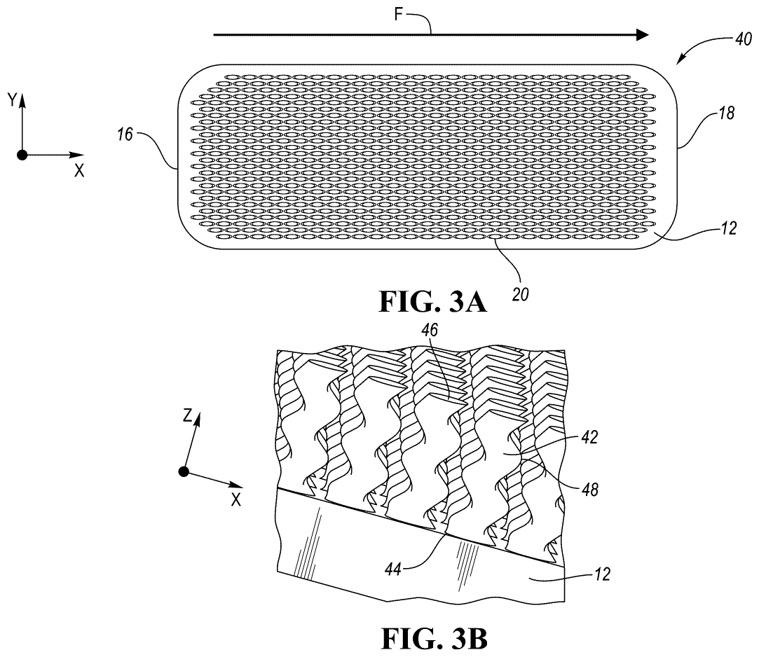

FIG. 3A-3B illustrate another embodiment in which corrugations can aid the fins in heat transfer. Referring to FIGS. 3A-3B, once again a heat sink 40 is illustrated. It should be understood that the heat sink 40 of this embodiment can incorporate all of the features of the heat sink 10 of FIGS. 1A-1B and/or heat sink 30 of FIGS. 2A-2B, unless the description and context described herein dictates otherwise. Here again, the heat sink 40 includes a plurality of fins 42 extending in the vertical (e.g., Z-axis) direction from the base 12. Each fin 42 has a lower edge 44 adjacent or integrated with the upper surface of the base 12, and an opposing upper edge 46 spaced from the base 12.

In this illustrated embodiment, the fins 42 are corrugated in the vertical direction; the corrugations are vertical corrugations. In other words, as opposed to the embodiment of FIGS. 2A-2B in which the corrugations are in the horizontal direction, here the corrugations 48 are in the vertical direction. This is shown in FIG. 3B, which is a vertical cross-section of the fins 4, as opposed to a horizontal cross-section. It can be said that the vertical corrugations are visible, and extend in, a vertical plane of the fins. A horizontal cross-section of the fins 42 (not shown) would not show corrugations (however, in other embodiments, there can be horizontal and vertical corrugations combined).

It can therefore be said that the fins 42 can take the general shape of a wave in the vertical direction—as the fins 42 extend away from the base 12, they are formed in a general wave pattern. And, while FIG. 3B shows the fins 42 waving back-and-forth in the X-direction, the fins can also wave back-and-forth in the Y-direction. Further, while FIG. 3B shows each fin 42 with a corrugation wave having between two and three periods, it should be understood that the number of waves or corrugations can be more or less than this depending on the particular application or desired characteristics.

As shown in FIG. 3B, the thickness of each fin 42 can be uniform throughout the vertical direction. However, in other embodiments, the thickness can be non-uniform, such as for example thicker near the lower edge 44 than near the upper edge 46.

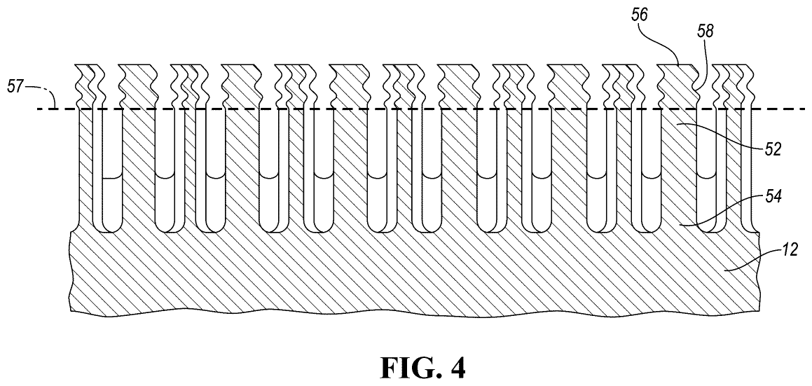

Moreover, the present disclosure is not limited to fins having vertical corrugations that extend entirely from the lower edge 44 to the upper edge 46. In other embodiments, only a portion of the height of the fins is provided with the vertical corrugations. For example, FIG. 4 illustrates an embodiment in which fins are corrugated only at their tips. Once again, it should be understood that the heat sink and fins of this embodiment can incorporate all of the features of the heat sinks and/or fins of the previously-described embodiments, unless the description and context described herein dictates otherwise. Once again, the heat sink can be provided with fins 52 that extend vertically from the base 12 from a lower edge 54 to an upper edge 56. The fins 52 have vertical corrugations 58 that extend in a vertical direction. However, in this embodiment, the corrugations are only in an upper region of the fins 52.

In particular, each fin 52 has a lower edge 54 adjacent or contiguous with the base 12, and an opposing upper edge 56. At a lower region of the fins 52 (e.g., below boundary line 57), the fins 52 extend generally vertically from the base 12 with no corrugations. In other words, the outer surfaces of the fins 52 are generally vertical and smooth with no undulations. At an upper region of the fins 52 (e.g., above boundary line 57), the fins 52 are provided with corrugations 58. Once again, these corrugations 58 are vertical corrugations in that they are visible in a vertical cross-section of the fins, such as the view taken in FIG. 4; a horizontal cross-section of the fins 52 may not show any corrugations in the outer surface of the fins 52.

The boundary line 57 separates the upper region of the fins 52 that is provide with corrugations 58 from the lower region of the fins 52 that do not have corrugations. It should be understood that this boundary line 57 can be located higher or lower than illustrated in FIG. 4, and can follow any arbitrary shape like a curved path, not necessarily a straight line. In other words, the size of the upper regions of the fins 52 that have the corrugations can be tailored to suit a particular heat transfer need.

The placement of corrugations 58 in the upper region of the fins 52, as opposed to throughout the entire fin 52, can offer several advantages. For one, placing corrugations only in the upper region focuses the turbulence-inducing effects of the corrugations on the portion of the fin 52 where fluid velocities are generally lower. In many systems, the flow near the upper portion of fins tends to be less turbulent due to the reduced interaction with the bulk fluid. Introducing corrugations in this region disrupts the thermal boundary layer effectively, increasing local heat transfer.

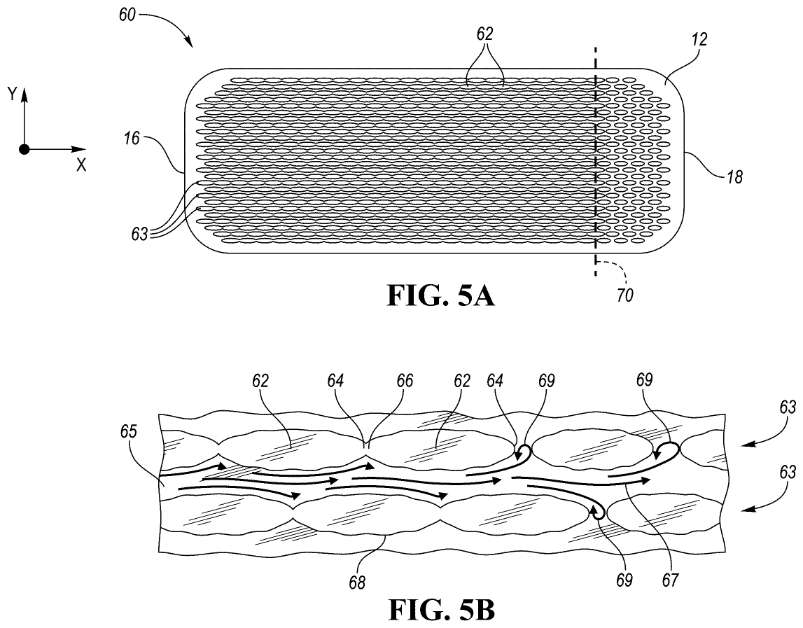

The teachings described herein can also apply to embodiments in which fins are joined. For example, referring to FIGS. 5A-5B, a heat sink 60 includes a base 12 and a plurality of fins 62 extending upwardly or outwardly from the base 12. Once again, it should be understood that the heat sink 60 of this embodiment can incorporate all of the features of the heat sinks of the previously-described embodiments, unless the description and context described herein dictates otherwise. In this embodiment, the plurality of fins 62 are arranged in rows 63 that extend laterally from the inlet region 16 to the outlet region 18. Each row 63 of fins is spaced apart from other rows 63 of fins to define channels 65 for the fluid to flow through, as indicated by velocity vector 67. Within each row, at least one of the fins 62 is joined to an adjacent fin 62. In particular, a trailing end 64 of one fin 62 is joined or integral with a leading end 66 of an adjacent fin 62. This forms a contiguous surface without gaps between two adjacent fins 62. This prevents the fluid from flowing between joined fins.

However, not all fins 62 need to be joined. For example, some of the leading ends 64 can be spaced from the adjacent trailing ends 66. This is also shown in FIG. 5B, allowing fluid to travel between those adjacent fins 62 as indicated by velocity vector 69. In some embodiments, fins of a common row to one side of a boundary line 70 are joined, while fins of a common row on another side of the boundary line 70 are not joined, as shown in FIG. 5A. The boundary line 70 is shown as a mere example in this Figure; it may be placed in other locations, and it may not be linear, depending on the application.

The fins 62, including both joined fins and non-joined fins, can have corrugations such as those described herein. For example, as shown in FIG. 5B, the fins 62 have horizontal corrugations 68. These corrugations 68 can extend about the horizontal perimeter of the fins 62. For example, in the case of joined fins, the corrugations 68 can extend from the leading end 64 to the trailing end 66, on both sides of the fin, and through the intersection of two joined fins. In embodiments, the corrugations can extend contiguously through a row 63 of joined fins 62. This provides an uninterrupted, enlarged surface for heat exchange, improving the overall heat transfer rate. Also, a joined fin design can ensure heat is distributed more evenly across the row 63; the corrugations 68 can create periodic disruptions in the thermal boundary layer along the entire row 63, preventing the boundary layer from thickening excessively, increasing convective heat transfer coefficient. Additionally, without gaps between the fins 62, the corrugations can create flow disturbances that minimize stagnation (which might occur with smooth surfaces in joined fins), ensuring that fresh, cooler fluid continuously interacts with the fin surface.

It should be understood that the present disclosure is not limited to only the corrugations illustrated. For example, in embodiments with joined fins such as in FIGS. 5A-5B, some of the joined fins may have corrugations, and some may not; some rows 63 may have corrugations, and some may not.

Furthermore, it should be understood that the teachings of one embodiment can be combined with another embodiment, although not illustrated in the Figures. For example, an embodiment with joined fins can include vertical corrugations (see FIG. 3B), or corrugations on only the upper regions of fins (see FIG. 4).

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A heat sink comprising:
a base; and
a plurality of joined fins extending upwardly from the base, wherein the joined fins are arranged in rows along a longitudinal direction to define channels between the rows, wherein each joined fin of each row is joined to an adjacent one of the joined fins in the same row such that each row of the joined fins is contiguous to inhibit fluid from flowing from one of the channels to another of the channels;
wherein each of the joined fins has a corrugated outer surface.

2. The heat sink of claim 1, wherein the corrugated outer surface includes a series of ridges and grooves.

3. The heat sink of claim 1, wherein the corrugated outer surface includes horizontal corrugations that extend in a horizontal direction.

4. The heat sink of claim 3, wherein the horizontal corrugations extends about an entire periphery of the joined fins.

5. The heat sink of claim 3, wherein the horizontal corrugations extend about only a portion of each of the joined fins.

6. The heat sink of claim 5, wherein the horizontal corrugations extend about a trailing side, but not a leading side, of the joined fins.

7. The heat sink of claim 3, wherein the horizontal corrugations are contiguous between adjacent joined fins.

8. The heat sink of claim 1, further comprising:
a plurality of non-joined fins extending upwardly from the base, wherein the non-joined fins do not intersect any of the other non-joined fins or joined fins.

9. The heat sink of claim 8, wherein each of the rows includes some of the joined fins and some of the non-joined fins.

10. The heat sink of claim 1, wherein each of the joined fins has a generally elliptical shape.

11. A heat sink comprising:
a base having an inlet region configured to receive incoming fluid, and an outlet region on an opposite end of the base from the inlet region; and
a plurality of fins extending upwardly from the base, each fin having a leading surface facing the inlet region and a trailing surface facing the outlet region;
wherein at least one of the leading surfaces or the trailing surfaces are corrugated.

12. The heat sink of claim 11, wherein the trailing surfaces are corrugated and include a series of ridges and grooves.

13. The heat sink of claim 12, wherein the series of ridges and grooves extend in a plane that extends longitudinally from the inlet region to the outlet region.

14. The heat sink of claim 11, wherein the entire leading surfaces are smooth, and the entire trailing surfaces are corrugated.

15. The heat sink of claim 11, wherein the plurality of fins are arranged in rows along a longitudinal direction to define channels between the rows, wherein the leading surface of each fin of a first of the rows is joined to the trailing surface of an adjacent fin in the same one of the rows.

16. A heat sink comprising:
a base having an inlet region configured to receive incoming fluid, and an outlet region on an opposite end of the base from the inlet region; and
a plurality of fins extending upwardly from the base, each fin having a lower region adjacent to the base and an upper region;
wherein at least one of the lower region and upper region of each fin has a vertical cross-sectional profile that includes a plurality of vertical corrugations.

17. The heat sink of claim 16, wherein the lower region of each fin includes the plurality of vertical corrugations, and wherein the upper region of each fin is smooth and does not include corrugations.

18. The heat sink of claim 16, wherein each fin includes a lower edge at the base, and an upper tip spaced from the base, and
wherein a boundary separates the lower region from the upper region, the boundary closer to the tip than the base.

19. The heat sink of claim 16, wherein the plurality of fins are arranged in rows along a longitudinal direction to define channels between the rows, wherein a leading surface of each fin of a first of the rows is joined to a trailing surface of an adjacent fin in the same one of the rows.

20. The heat sink of claim 16, wherein the upper region of each fin has a horizontal cross-sectional profile that has a generally elliptic shape and includes a plurality of horizontal corrugations.
